(19) United States
(12) Patent Application Publication
(10) Pub. No.: US 2023/0290663 A1
(43) Pub. Date: Sep. 14, 2023

(54) PRINTING COMPONENTS SUSPENDED BY FRAMES

(71) Applicant: X-Celeprint Limited, Dublin (IE)

(72) Inventors: António José Marques Trindade, Cork (IE); Ronald S. Cok, Rochester, NY (US)

(21) Appl. No.: 17/693,253

(22) Filed: Mar. 11, 2022

(51) Int. Cl. H01L 21/683; H01L 41/047; H01L 41/053; H01L 41/23; H01L 41/29; B41F 16/00

(52) U.S. Cl. CPC H01L 21/6835; H01L 41/0475; H01L 41/053; H01L 41/23; H01L 41/29; B41F 16/00; H01L 2221/68318; H01L 2221/68354; H01L 2221/68363

(57) ABSTRACT

According to embodiments of the present disclosure a micro-device comprises a frame and a component separated from the frame by a gap except where the component is connected to the frame with cantilever supports extending from the component to the frame. The internal frame contour of the frame can be non-rectangular. The external contour of the frame can be rectangular. The frame can follow the external contour of the component and cantilever supports except where the cantilever supports are connected to the frame. The internal or external contour of the frame can comprise slits extending into the frame. The gap separating the frame from the component can have a uniform width except where the cantilever supports are connected to the frame. In some embodiments, a micro-device is disposed on a target substrate comprising a cavity and the component is suspended over the cavity.

### TECHNICAL FIELD

The present disclosure relates generally to printed or printable structures and methods including micro-assembled devices and components.

### BACKGROUND

Substrates with electronically active components distributed over the extent of the substrate may be used in a variety of electronic systems, for example, in flat-panel display devices such as flat-panel liquid crystal or organic light emitting diode (OLED) displays, in imaging sensors, and in flat-panel solar cells. The electronically active components are typically either assembled on the substrate, for example using individually packaged surface-mount integrated-circuit devices and pick-and-place tools, or by sputtering or spin coating a layer of semiconductor material on the substrate and then photolithographically processing the semiconductor material to form thin-film circuits on the substrate. Individually packaged integrated-circuit devices typically have smaller transistors with higher performance than thin-film circuits but the packages are larger than can be desired for highly integrated micro-systems.

Other methods for transferring active components from one substrate to another are described in U.S. Pat. No. 7,943,491. In an example of these approaches, small integrated circuits are formed on a native semiconductor source wafer. The small unpackaged integrated circuits, or chiplets, are released from the native source wafer by etching a layer formed beneath the circuits. A viscoelastic stamp is pressed against the native source wafer and the process side of the chiplets is adhered to individual stamp posts. The chiplets on the stamp are then pressed against a destination substrate or backplane with the stamp and adhered to the destination substrate. In another example, U.S. Pat. No. 8,722,458 entitled Optical Systems Fabricated by Printing-Based Assembly teaches transferring light-emitting, light-sensing, or light-collecting semiconductor elements from a wafer substrate to a destination substrate or backplane.

Micro-electro-mechanical systems (MEMS) are used for many applications, including processing and controlling electronic and optical signals. Such systems incorporate small mechanical structures made using photolithographic methods and materials and can be integrated into electronic, optical, or electro-optic systems. For example, accelerometers, interferometric modulators, scanners, gyroscopes, piezoelectric energy harvesting, and pressure sensors can be constructed using such techniques. Resonant MEMS devices with electrodes can be used to process signals and produce energy from mechanical manipulation, for example as in acoustic wave filters. Typical designs can have solidly mounted beams or beams that are anchored on one or both ends or sides, for example as discussed in U.S. Pat. Nos. 7,984,648, 8,827,550, 7,990,233, U.S. Patent Application Publication No. 2010/0189444, and PCT Publication No. WO 2011/129855.

There remains an on-going need for structures that are readily constructed with improved performance and that are or can be integrated or micro-assembled into electronic and micro-electro-mechanical systems.

### SUMMARY

The present disclosure provides, inter alia, structures, materials, and methods for enabling the release of micro-devices from a source wafer (source substrate) and transfer printing (e.g., micro-transfer printing) the micro-devices from the source wafer to a target substrate.

According to embodiments of the present disclosure a micro-device comprises a frame and a component separated from the frame by a gap except where the component is connected to the frame with one or more cantilever supports (e.g., two) extending from the component across the gap to the frame. An internal frame contour of the frame can be non-rectangular. An external contour of the frame can be rectangular. The internal contour of the frame can follow an external contour of the component and the one or more cantilever supports except where the one or more cantilever supports are connected to the frame. The internal contour of the frame can comprise one or more slits extending from the gap into the frame. The external contour of the frame can comprise one or more slits extending into the frame. The gap separating the frame from the component can have a substantially common or uniform width except where the one or more cantilever supports are connected to the frame.

According to embodiments of the present disclosure, the component can be substantially rectangular. The component can comprise a piezoelectric material and electrodes, and the electrodes can extend over the cantilever supports to the frame. The micro-device can comprise a piezoelectric material and electrodes.

In some embodiments, the frame or micro-device can comprise at least a portion of a tether and can extend from the frame. In some embodiments, the frame can comprise one or more of the materials comprising the component so that the frame and the component can each comprise one or more same materials.

Some embodiments of the present disclosure can comprise a cap disposed over the frame and component and adhered to the frame.

In some embodiments, the one or more cantilever supports is a plurality of cantilever supports. In some embodiments, the plurality of cantilever supports comprises cantilever supports that connect to the component at different sides of the component, for example on opposing sides of a rectangular or polygonal component.

Some embodiments of the present disclosure can comprise a target substrate and one or more micro-device(s) disposed on the target substrate. The target substrate can comprise a cavity and the component can be disposed on and suspended over the cavity in the target substrate. A cap can be disposed over the micro-device, frame, and component and adhered to the target substrate.

According to embodiments of the present disclosure, a micro-device wafer can comprise a source wafer comprising a sacrificial layer and the sacrificial layer can comprise a sacrificial portion adjacent to an anchor. A micro-device can be disposed entirely and directly over the sacrificial portion in a direction orthogonal to a surface of the sacrificial portion on or over which the micro-device is disposed. The sacrificial portion can be a space between the source wafer and the micro-device, and the micro-device can be attached to the anchor with a tether and suspended over the space.

According to embodiments of the present disclosure, a method of making a micro-device structure comprises providing a source wafer comprising a sacrificial layer comprising sacrificial portions separated by anchor portions, forming a plurality of micro-devices each comprising a frame and a component separated from the frame by a gap except where the component is connected to the frame with cantilever supports extending from the component across the gap to the frame, each of the micro-devices disposed entirely directly over one of the sacrificial portions, optionally disposing a cap over the micro-device and adhering the cap to the frame of the micro-device, releasing the micro-devices by etching the sacrificial portions, micro-transfer printing the micro-devices from the source wafer to a target substrate, and optionally disposing a cap over the micro-device and adhering the cap to the target substrate. In some embodiments, printing the micro-devices comprises micro-transfer printing the micro-devices with a stamp, wherein the stamp comprises posts and each of the posts has a distal end having a shape corresponding to the frame of one of the micro-devices such that the post contacts the frame and not the component of the one of the micro-devices during micro-transfer printing.

According to embodiments of the present disclosure, a micro-device, comprises a frame, a component separated from the frame by a gap and connected to the frame only with one or more cantilever supports extending from the component across the gap to the frame. The frame can comprise one or more slits extending into the frame. The internal contour of the frame can comprise one or more slits extending from the gap into the frame. The external contour of the frame can comprise at least one of the one or more slits extending into the frame.

According to embodiments of the present disclosure, a micro-structure comprises a target substrate comprising a cavity and a micro-device disposed on or over the target substrate such that the component is disposed or suspended over the cavity, for example directly over the cavity in a direction orthogonal to a surface of the target substrate on or over which the micro-device is disposed.

According to some embodiments, the transfer device is a stamp comprising a stamp post, one of the picked-up micro-devices is disposed on the stamp after being picked up, and the stamp post has an external dimension substantially the same as a corresponding external dimension of at least one of the micro-devices.

In some embodiments, a micro-device comprises a frame and a component suspended from the frame. The micro-device, frame, or component can have at least one of an exterior length and a width less than or equal to 1 mm, less than or equal to 500 μm, less than or equal to 200 μm, less than or equal to 100 μm, less than or equal to 50 μm, less than or equal to 20 μm, less than or equal to 10 μm, or less than or equal to 5 μm. micro-device, frame, or component can have a thickness of no greater than 100 μm, no greater than 50 μm, no greater than 20 μm, no greater than 10 μm, no greater than 5 μm, or no greater than 2 μm. The micro-device, frame, or component can comprise a material that is a semiconductor, a piezoelectric material, a conductive material such as metal, and a dielectric material. micro-device, frame, or component can comprise any one or combination of SiO2, SiNx, KNN (potassium sodium niobate), MN (aluminum nitride), PZT (lead zirconate titanate), aluminum, silver, copper, and gold. The component can be an electronic component, an opto-electronic component, a piezo-electric component, a resonator component, an acoustic filter, or a micro-electro-mechanical structure and can comprise an active or passive electrical circuit. The component can be responsive to at least one of electrical energy, optical energy, electromagnetic energy, and mechanical energy.

The micro-device can be adhered or attached to a target substrate only by a micro-device bottom side. The micro-device can comprise electrically conductive connection posts. In some embodiments, a micro-device comprises two, three, or at least four connection posts

The component can be suspended over a target substrate or over a cavity in the target substrate. In some embodiments, the target substrate is a semiconductor substrate (e.g., a silicon or compound semiconductor substrate) comprising one or more electronic substrate circuits, the target substrate is a glass substrate, or the target substrate is a polymer substrate. The electronic substrate circuit(s) can be electrically connected to the micro-device.

In some embodiments, the micro-device has a top side and a bottom side opposite the top side and the micro-device comprises a component top electrode disposed on the top side of the component that can extend over at least a portion of the frame, for example a top side of the frame. In some embodiments, the micro-device comprises a component bottom electrode disposed on the bottom side of the component. The bottom electrode can pass through a via and extend over at least a portion of the frame, for example a top side of the frame.

In some embodiments, the frame comprises a dielectric layer and one or more connection posts that extend from the dielectric layer. The connection posts can each be electrically connected to an electrode (e.g., a connection post can be electrically connected to a top electrode and a connection post can be electrically connected to a bottom electrode). The connection posts can each have a distal end and a proximal end, the distal end having an area smaller than an area of the proximal end, wherein the distal end forms a sharp point. The connection posts can comprise planar edges or a pyramidal structure.

In some embodiments, a micro-device source wafer comprises a sacrificial layer comprising sacrificial portions and each sacrificial portion is adjacent to one or more anchors. A micro-device can be disposed entirely, completely, or exclusively over each of the sacrificial portions in a direction orthogonal to a surface of the micro-device source wafer on which the micro-device is disposed. In some embodiments, the micro-devices can comprise portions that extend over or form part of a micro-device tether or anchor, for example encapsulation layers or dielectric substrate layers. In some embodiments, the micro-device source wafer comprises trenches, pits, indentations, or holes in which connection posts are disposed or formed.

In some embodiments, a printed micro-device structure comprises a target substrate having a target substrate surface, substrate electrodes (e.g., substrate contact pads) disposed on the substrate surface, and a micro-device disposed on the substrate surface. The micro-device can comprise electrodes that are electrically connected to the substrate electrodes or contact pads. In some embodiments, the micro-device comprises connection posts that are in electrical contact with (e.g., embedded in or piercing) the substrate electrodes or contact pads. According to some embodiments, the substrate electrodes are substantially planar.

According to some embodiments of the present disclosure, solder is disposed on the substrate electrodes and the solder coats at least a portion of the connection posts. According to some embodiments, a non-directional deposition of metal coats both the connection posts and the substrate electrodes, for example by chemical vapor, electroless plating, or electroplating. According to some embodiments, the connection posts are wave soldered. Heating and then cooling the solder can physically connect each of the connection posts to one of the substrate electrodes.

In some embodiments, a printed micro-device structure comprises a patterned layer of adhesive adhering any one or more of the connection posts or the frame to the substrate surface. The patterned layer of adhesive can contact only a portion of a bottom surface of the micro-device to the substrate surface (e.g., the frame).

The adhesive can be a cured adhesive, an uncured adhesive, a partially cured adhesive, or a soft-cured adhesive. The adhesive can be a curable adhesive that is only partially cured. The adhesive can comprise an organic material, a polymer, a resin, or an epoxy. The adhesive can be a photoresist. The photoresist can be a positive photoresist or a negative photoresist. According to some embodiments of the present disclosure, the adhesive holds the component in compression against the substrate.

According to some embodiments of the present disclosure, each of the micro-devices picked up by a micro-transfer printing stamp comprises a broken (e.g., fractured) or separated micro-device tether, for example as a consequence of micro-transfer printing the micro-device from a micro-device source wafer to the substrate post.

According to embodiments of the present disclosure, micro-devices comprising components suspended from a frame by cantilever supports can be smaller, use less power, and enable more highly integrated electronic systems incorporating the micro-devices. In some embodiments, some such micro-devices are integrated with target substrates comprising different materials from the micro-device or component. Target substrates can comprise a cavity over which the component is suspended.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1A is a plan view of a micro-device comprising a component physically connected to a frame with cantilever supports and FIG. 1B shows the internal and external frame contours (perimeters or outlines) of the frame according to illustrative embodiments of the present disclosure;

FIG. 2A is a cross section of FIG. 1A taken across cross section line A and FIG. 2B is a cross section of FIG. 1A taken across cross section line B of a micro-device disposed on a micro-device source wafer according to illustrative embodiments of the present disclosure;

FIG. 3 is a cross section of a micro-device corresponding to cross section line A of FIG. 1A released from a micro-device source wafer according to illustrative embodiments of the present disclosure;

FIG. 4 is a plan view of multiple micro-devices on a micro-device source wafer according to illustrative embodiments of the present disclosure;

FIG. 5A is a plan view of a micro-device micro-transfer printed onto a target substrate with a cavity according to illustrative embodiments of the present disclosure;

FIG. 5B is a cross section of micro-transfer printing a micro-device with a stamp onto a target substrate with a cavity taken along cross section line A of FIG. 5A according to illustrative embodiments of the present disclosure;

FIG. 6 is a flow diagram of methods according to illustrative embodiments of the present disclosure;

FIG. 7 is a cross section of a micro-device taken along cross section line B of FIG. 1A micro-transfer printed onto a target substrate with a cap and electrically connected electrodes according to illustrative embodiments of the present disclosure;

FIG. 8 is a cross section of a micro-device source wafer and released micro-device with connection posts taken along cross section line B of FIG. 1A according to illustrative embodiments of the present disclosure;

FIG. 9 is a cross section of a micro-device with connection posts according to FIG. 8 micro-transfer printed onto a target substrate according to illustrative embodiments of the present disclosure;

FIG. 10 is a cross section of a micro-device with connection posts according to FIG. 8 micro-transfer printed onto a target substrate with a cap according to illustrative embodiments of the present disclosure;

FIG. 11 is a perspective of a stamp post with a distal end corresponding to a shape of a micro-device frame according to illustrative embodiments of the present disclosure;

FIG. 12 is a mask of a micro-device according to illustrative embodiments of the present disclosure; and

FIG. 13 is a plan view of a constructed micro-device according to illustrative embodiments of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not necessarily drawn to scale. The vertical scale of the Figures can be exaggerated to clarify the illustrated structures.

### DETAILED DESCRIPTION OF CERTAIN EMBODIMENTS

Electronic circuit performance and density are important attributes of electronic systems. Embodiments of the present disclosure provide a micro-device comprising a component attached to a frame that can be or is micro-transfer printed, for example from a micro-device source wafer to a target substrate. The component can be suspended from the frame with one or more cantilever supports (for example two cantilever supports) and is otherwise free to move. For example, in some embodiments, a micro-device is a micro-electro-mechanical device such as an acoustic resonator or filter. The micro-device can be very small and thin, enabling systems of reduced size and efficient performance, for example micro-systems.

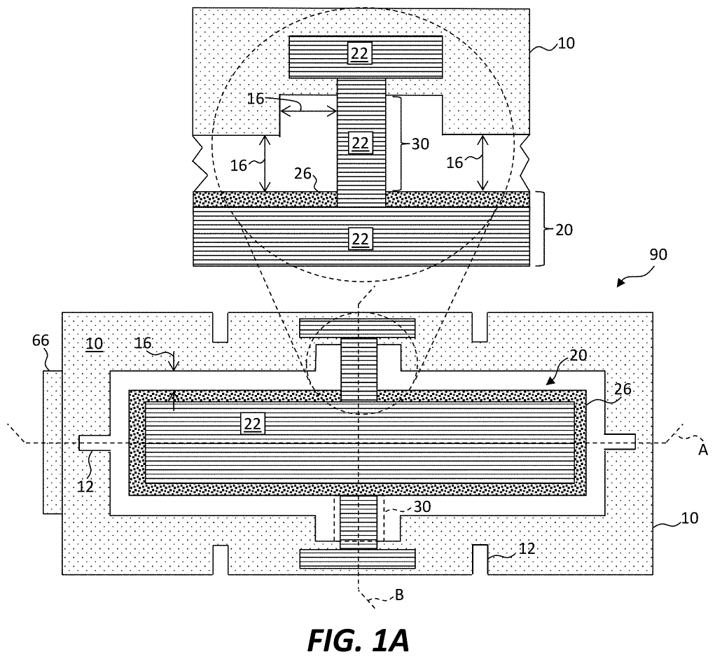

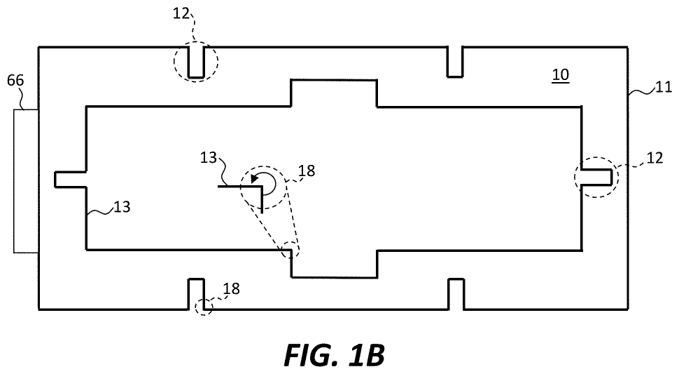

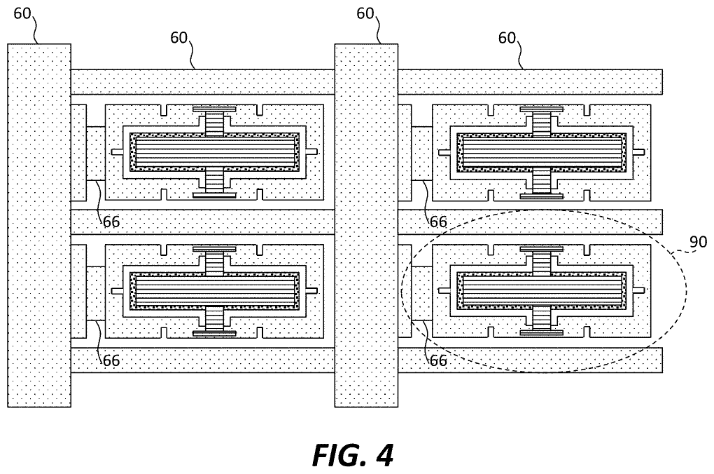

According to embodiments of the present disclosure and as illustrated in FIGS. 1A-1B, a micro-device 90 comprises a frame 10 and a component 20 separated from the frame 10 by a gap 16 except where component 20 is connected to frame 10 with one or more (e.g., two) cantilever supports 30 extending from component 20 across gap 16 to frame 10. Component 20 can be a micro-component with one or more dimensions less than one mm. As shown in the outlines of FIG. 1B, in some embodiments, an internal frame contour 13 (e.g., interior perimeter or outline) of frame 10 is non-rectangular, for example following and spaced apart (separated) from an external contour (e.g., external perimeter or outline) of component 20 and cantilever supports 30 except where cantilever support(s) 30 are connected to frame 10. (FIGS. 4 and 13 show additional examples of such an arrangement.) In some embodiments, such an arrangement has a uniform gap width between frame 10 and component 20/cantilever support(s) 30 except where cantilever support(s) 30 are connected to frame 10, for example as shown in FIGS. 1A-1B (and 4 and 13). Frame 10 can comprise one or more slits 12 extending into frame 10. A slit 12 can be a straight and narrow cut, opening, or aperture in frame 10 that extends from an internal or external edge of frame 10 into frame 10. Slit(s) 12 can expose or form one or more exposed corners 18 in frame 10. In some embodiments, frame 10 extends from interior frame contour 13 into frame 10, for example from an interior frame perimeter or from gap 16 into frame 10. In some embodiments, one or more slits 12 extend from an exterior (external) frame contour 11 (e.g., exterior perimeter or outline). In some embodiments, slits 12 extend into frame 10 from both exterior frame contour 11 and interior frame contour 13, as shown in FIGS. 1A-1B. In some embodiments, internal frame contour 13 of frame 10 is non-rectangular excluding slits 12. Where frame 10 does not comprise slits 12, frame 10 can have a rectangular external frame contour 11. In some embodiments, component 20 is substantially rectangular (e.g., within manufacturing tolerances). An external contour can be a perimeter, shape, or outline of a structure. An internal contour can be an outline, shape, or perimeter of a hole or absence of material in a structure.

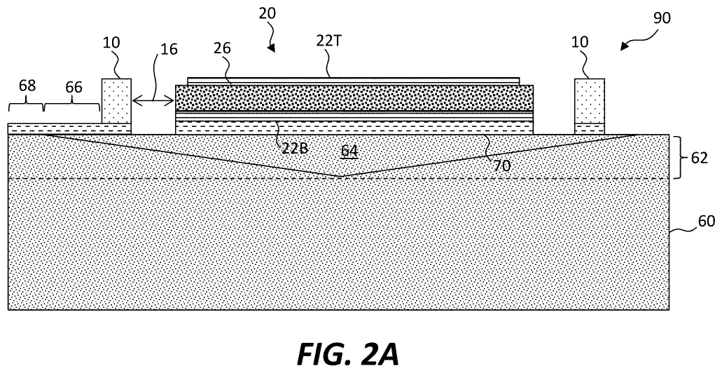

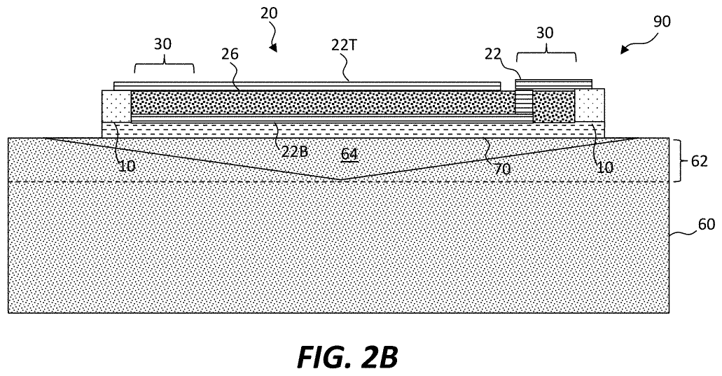

According to some embodiments of the present disclosure and as also shown in the cross sections of FIGS. 2A and 2B corresponding to cross section lines A and B of FIG. 1A, component 20 can comprise a component material 26, (e.g., a piezoelectric material) and one or more micro-device electrodes 22 disposed on one or more sides of component material 26 (e.g., one at least partially on top and one at least partially on bottom of component 20). Micro-device electrodes 22 can extend from component 20 over cantilever supports 30 onto frame 10, as shown in FIG. 2B. A micro-device electrode 22 can be disposed on a top (top electrode 22T) and a bottom (bottom electrode 22B) of component material 26 or micro-device electrodes 22 can be patterned on one side of the material. Bottom electrode 22B can pass through a via in component material 26 and extend onto a top side of cantilever support 30 and frame 10. Micro-device electrodes 22 on frame 10 can provide electrical connections to external electronic circuits to electrically control or respond to component 20. According to some embodiments, multiple different micro-device electrodes 22 can be disposed on a side of component 20, for example as interdigitated micro-device electrodes 22 on a top side of component 20. Examples of such electrodes 22 are shown in U.S. patent application Ser. No. 17/027,671, whose contents are incorporated herein by reference in their entirety. Top and bottom are arbitrary designations but generally refer to opposite sides of a structure such as component 20.

According to some embodiments, frame 10 can comprise one or more materials as are comprised in component 20, e.g., component material 26, micro-device electrodes 22 (e.g., a metal) or one or more other materials including oxides such as silicon dioxide or nitrides such as silicon nitride. According to some embodiments, frame 10 or micro-device 90 is micro-transfer printable or micro-transfer printed and comprises a micro-device tether 66 or a broken (e.g., fractured) or separated micro-device tether 66. Micro-device tether 66 can comprise one or more of component material 26, dielectric materials such as an oxide or nitride in various combinations, metals, a photoresist, an encapsulating layer, or an etch-stop layer 70 as described further below.

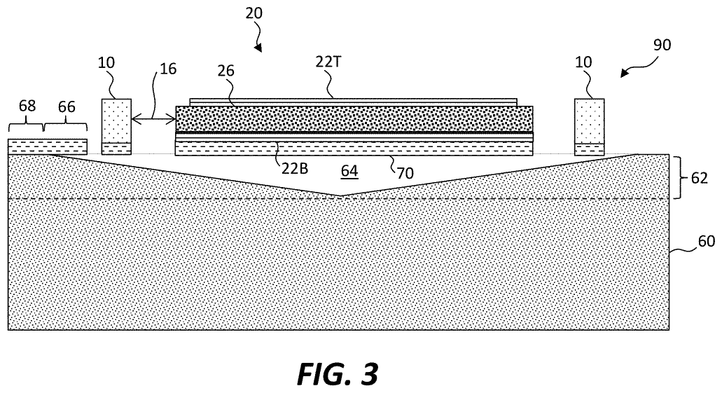

According to embodiments of the present disclosure and as illustrated in FIGS. 2A and 2B, micro-device 90 can be constructed on a micro-device source wafer 60 and micro-transfer printed to a target substrate. Micro-device source wafer 60 comprises a sacrificial layer 62 with sacrificial portions 64 separated by or adjacent to anchors 68. Etch-stop layer 70 is disposed over and patterned on sacrificial layer 62. Micro-device 90 is directly and entirely disposed over etch-stop layer 70 and sacrificial portion 64 and is physically connected to anchor 68 by micro-device tether 66. In FIG. 2A, micro-device tether 66 is illustrated as comprising etch-stop layer 70 but can comprise other material(s). Sacrificial portion 62 can be differentially etched with respect to etch-stop layer 70 to form an empty space and suspend micro-device 90 over the space (etched sacrificial portion 64) by micro-device tether 66, as shown in FIG. 3 using micro-device 90 cross section A of FIG. 1A, to enable micro-transfer printing micro-device 90 from micro-device source wafer 60. FIG. 4 illustrates micro-device source wafer 60 with an array of micro-devices 90. Each micro-device 90 is connected to micro-device source wafer 60 with micro-device tether 66.

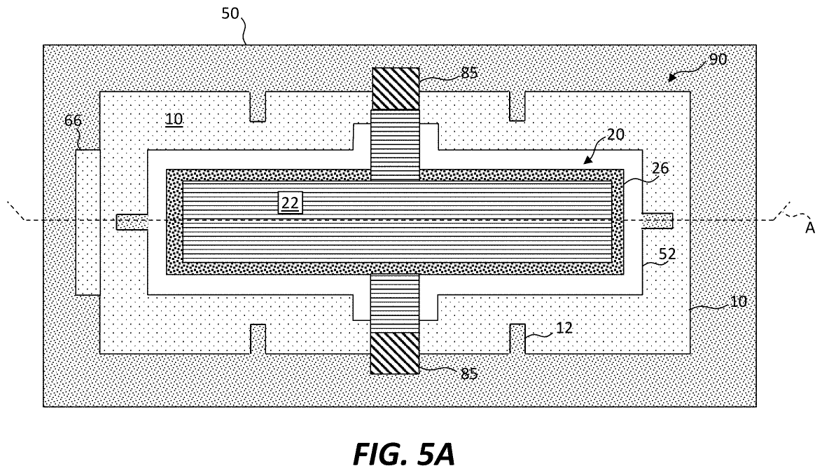

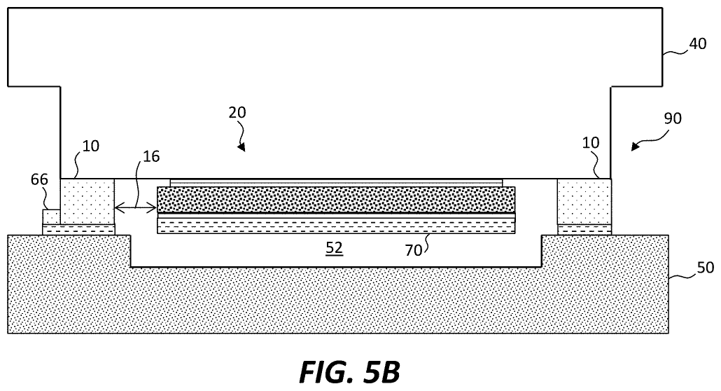

Micro-device 90 can be micro-transfer printed with a stamp 40 from a micro-device source wafer 60 to a target substrate 50 comprising a substrate cavity 52 so that component 20 is suspended over substrate cavity 52, for example as shown in FIG. 5B. Micro-device 90 can be aligned with substrate cavity 52 when printing with stamp 40 so that component 20 is completely, directly, and entirely disposed over substrate cavity 52, for example as shown in FIG. 5A. Thus, according to embodiments of the present disclosure, a micro-structure comprises a target substrate 50 comprising a substrate cavity 52 and a micro-device 90 disposed on or over the target substrate 50 such that component 20 is disposed and suspended over substrate cavity 52. By providing component 20 suspended over substrate cavity 52 by cantilever supports 30, component 20 is free to mechanically move (e.g., vibrate or oscillate) without impingement from other structures. In some embodiments, substrate cavity 52 provides a space (e.g., an air gap, vacuum gap, dry nitrogen gap, or other spacing) between target substrate 50 and component 20.

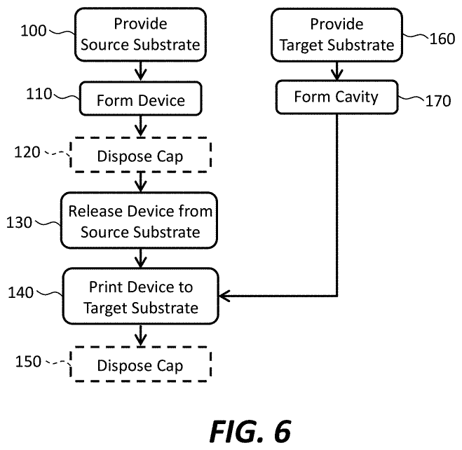

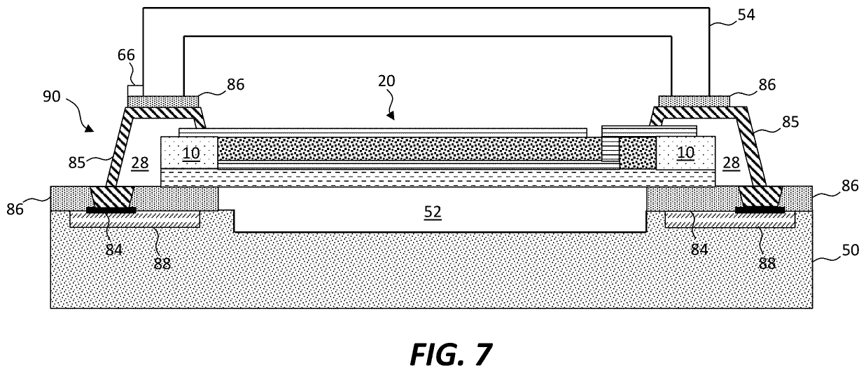

According to embodiments of the present disclosure and as illustrated in the flow diagram of FIG. 6, micro-devices 90 can be constructed in step 100 by first providing a micro-device source wafer 60 comprising a sacrificial layer 62 with sacrificial portions 64 separated by anchors 68. Micro-device source wafer 60 can be a semiconductor source wafer, for example a silicon source wafer. Etch-stop layer 70 is disposed over and patterned on sacrificial layer 62, as shown in FIGS. 2A and 2B. Etch-stop layer 70 can be an insulator, for example a dielectric layer such as an oxide or nitride layer and micro-device source wafer 60 can be a semiconductor-on-insulator wafer. In step 110, micro-device 90 can be constructed directly and entirely over etch-stop layer 70 and sacrificial portion 64, for example by depositing and patterning layers of material using photolithographic methods and materials. A micro-device electrode 22 layer can be deposited (e.g., by evaporation or sputtering a metal) on etch-stop layer 70 directly over sacrificial portion 64 and patterned to form bottom electrode 22B. A component material 26 layer can be deposited on the micro-device electrode 22 layer (e.g., by evaporation or sputtering, for example sputtering or evaporation of a piezoelectric material such as KNN, AlN, or PZT or a semiconductor epitaxial layer) and patterned to form a functional material. A micro-device electrode 22 layer can be deposited (e.g., by evaporation or sputtering a metal) on component material 26 and patterned to form top electrode 22T, in some embodiments thereby completing component 20, for example as shown in FIGS. 2A and 2B. The layers of material used to form component 20 can also form cantilever support 30 and frame 10. In some embodiments, different materials are deposited and patterned to form cantilever support 30 and frame 10. For example, frame 10 can comprise patterned dielectric structures 28 on which micro-device electrodes 22 are deposited and patterned. In some embodiments, bottom electrode 22B is omitted and multiple (e.g., two) top electrodes 22T are patterned on component material 26 and each top electrode 22T can be extended over a corresponding cantilever support 30 onto frame 10. Optionally, a cap 54 covering component 20 is disposed on frame 10 in optional step 120, for example by micro-transfer printing, as shown for example in FIG. 7.

In step 130, micro-device 90 is released from micro-device source wafer 60 by etching sacrificial portion 64 with an etchant through opening(s) in etch-stop layer 70 exposing sacrificial portion 64. After release, micro-device 90 is suspended over micro-device source wafer 60 by one or more micro-device tethers 66 connected to micro-device 90 and anchor 68, as shown in FIG. 3.

A target substrate 50 is provided in step 160 and patterned with a substrate cavity 52 in step 170, for example by etching through a patterned photoresist layer and then stripping the photoresist using photolithographic methods and materials. Target substrate 50 can be any suitable substrate, including a semiconductor, glass, ceramic, or polymer substrate.

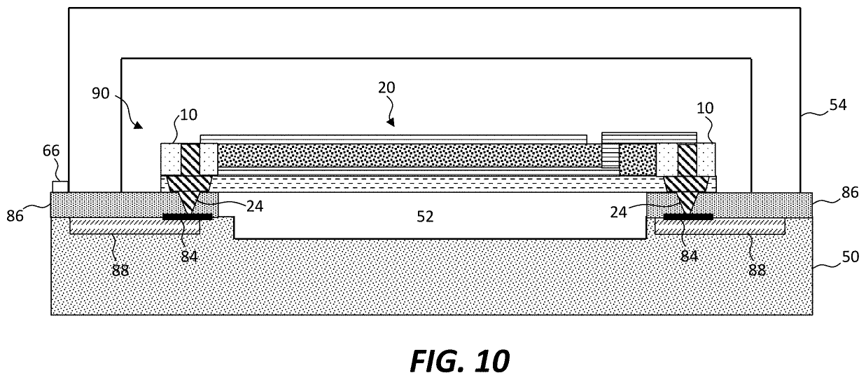

In step 140, micro-device 90 can be micro-transfer printed with a stamp 40 from micro-device source wafer 60 to target substrate 50 over substrate cavity 52, as shown in FIGS. 5A and 5B, so that component 20 is suspended over substrate cavity 52. Micro-device electrodes 22 can be electrically connected to substrate contact pads 84 with substrate electrodes 85, for example using photolithographic methods and materials. Cap 54 can be optionally disposed on and adhered to frame 10 (e.g., as shown in FIG. 7) or target substrate 50 (e.g., as shown in FIG. 10) in optional step 150. Micro-device 90 can then be operated by providing electrical control signals through substrate contact pads 84, substrate electrodes 85, and micro-device electrodes 22 to component 20, for example with a substrate circuit 88 native to target substrate 50 or a substrate circuit 88 disposed on target substrate 50, for example by photolithographic processing or by micro-transfer printing.

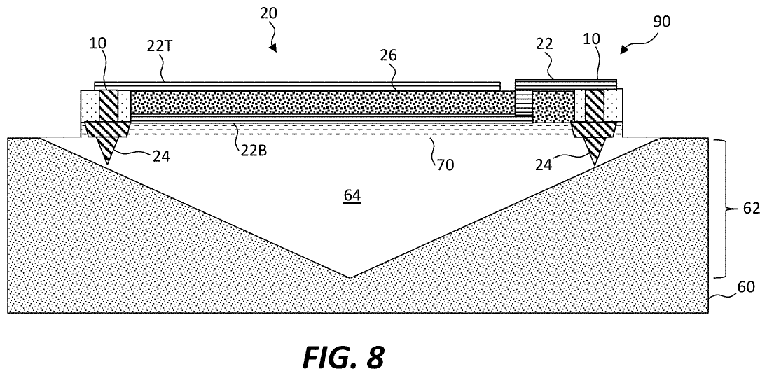

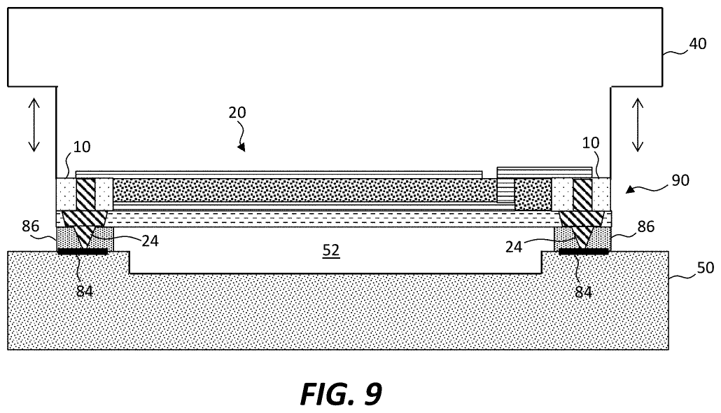

In some embodiments of the present disclosure, micro-devices 90 are electrically connected to substrate electrodes 85, contact pads 84, or substrate circuit 88 using photolithographically defined substrate electrodes 85 disposed over dielectric structures 28, for example as shown in FIG. 7. In some embodiments, frames 10 can comprise connection posts 24, for example formed in pyramidal depressions extending from etch-stop layer 70 in sacrificial portions 64 that are electrically connected to micro-device electrodes 22, for example through a via in etch-stop layer 70 and frame 10. Methods of making and connecting connection posts 24 are described at length in U.S. Pat. No. 10,468,363, entitled Chiplets with Connection Posts, the disclosure of which is hereby incorporated by reference in its entirety. After sacrificial portion 64 is etched to release micro-device 90 from micro-device source wafer 60 (e.g., in step 130), connection posts 24 extend into the space formed by etched sacrificial portion 64, for example as shown in FIG. 8. When micro-device 90 is micro-transfer printed from micro-device source wafer 60 to target substrate 50, connection posts 24 can be aligned with and pressed into or through contact pads 84 on target substrate 50 to form an electrical connection between connection posts 24 and contact pads 84 without any additional photolithographic processing, reducing manufacturing steps and costs, as shown in FIG. 9.

According to some embodiments, micro-device 90 is micro-transfer printed onto target substrate 50 without an adhesive layer adhering micro-device 90 to target substrate 50, as shown in FIG. 5B. In some embodiments, micro-device 90 is adhered to target substrate 50 with a layer of adhesive 86 as shown in FIGS. 7, 9, and 10. A curable adhesive 86 can be disposed on target substrate 50, for example by spray, spin, or slot coating the layer of adhesive 86. The layer of adhesive 86 can be patterned, for example removed from target substrate 50 except between frame 10 and target substrate 50. As micro-device 90 is disposed on target substrate 50 with stamp 40 (e.g., as in step 140 and FIG. 9), frame 10 contacts adhesive 86 and is adhered to target substrate 50, for example as shown in FIGS. 7, 9, and 10. If micro-device 90 comprises connection posts 24, connection posts 24 can be forced through adhesive 86 into contact with contact pads 84 in step 140. In some embodiments, when adhesive 86 is cured, it shrinks somewhat and pulls micro-device 90 toward target substrate 50 and, if present, forces connection posts 24 into or through contact pads 84, creating a firm electrical connection. If micro-device 90 does not comprise connection posts 24, electrical connections between target substrate 50 and micro-device 90 can be made using other means, such as conventional photolithographic methods and materials, e.g., as shown in FIG. 7. Adhesive 86 can also be used to adhere cap 54 to either frame 10 (e.g., as shown in FIG. 7) or target substrate 50 (e.g., as shown in FIG. 10).

According to embodiments of the present disclosure (and as shown in FIGS. 5A, 5B, and 7-10), components 20 are suspended by cantilever supports 30 and are not otherwise in contact with any other structure, for example not in contact with an underlying substrate, e.g., target substrate 50, (in contrast to, for example, solidly mounted bulk acoustic resonators). Thus, components 20 cannot be transferred directly from a micro-device source wafer 60 onto a target substrate 50 but rather require a supporting structure (e.g., frame 10) to suspend components 20 and enable micro-devices 90 transfer to a target substrate 50 and operation on target substrate 50, optionally over a substrate cavity 52 in target substrate 50 that enables component 20 operation and support exclusively by frame 10. Thus, frame 10 provides structural support to component 20 and also enables micro-transfer printing micro-device 90.

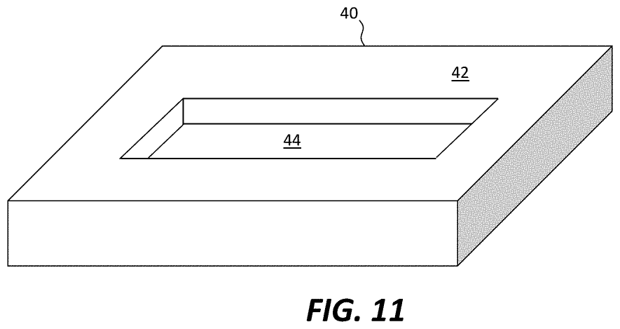

Micro-transfer printing uses a stamp 40 in contact with micro-device 90 to remove micro-device 90 from a micro-device source wafer 60 and transfer micro-device 90 to a target substrate 50. Since component 20 can be fragile and connected to frame 10 only by cantilever support(s) 30, a stamp 40 in contact with component 20 can break cantilever support(s) 30. Stamp 40 can have post with a distal end 42 having a shape corresponding to frame 10 and with a stamp opening 44 (e.g., a stamp cavity 44 in distal end 42 of stamp 40 post) corresponding to frame 10 and component 20 to avoid contacting component 20 and breaking cantilever supports 30 during the micro-transfer printing process as shown in FIG. 11. (FIG. 11 shows stamp 40 upside-down with respect to FIGS. 5B and 9.) In some embodiments, frame 10 has a thickness that is greater than a thickness of component 20 and component 20 is disposed in frame 10 such that frame 10 protrudes above component 20 such that stamp 40 only contacts frame 10 and not component 20 during printing.

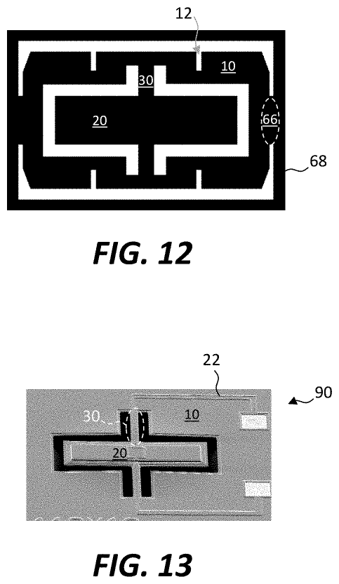

Some embodiments of the present disclosure have been constructed using photolithographic methods and materials. FIG. 12 shows a mask for constructing micro-device 90 that includes component 20 suspended by cantilever supports 30 to frame 10 and attached to anchor 68 with tethers 66 on either end of frame 10. FIG. 13 shows a corresponding constructed micro-device 90 with electrodes 22 electrically connected to test contact pads.

According to embodiments of the present disclosure, micro-device 90 or frame 10 can be a microscopic device with external dimensions less than 1 mm in length or width, or both, and, optionally, a thickness no greater than 1000 μm. For example, micro-device 90 or frame 10 can have a length of no greater than 500 μm, no greater than 300 μm, no greater than 200 μm, no greater than 100 μm, no greater than 50 μm, or no greater than 20 μm. In some embodiments, component 20 can be a microscopic device with external dimensions less than 500 μm in length or width, or both, and, optionally, a thickness no greater than 500 μm. For example, component 20 can have a length of no greater than 500 μm, no greater than 300 μm, no greater than 200 μm, no greater than 100 μm, no greater than 50 μm, no greater than 10 μm, or no greater than 5 μm, or no greater than 20 μm. In some embodiments, component 20 can have a length in the range of 200-300 μm, for example 270-280 μm. In some embodiments, frame 10 can have external dimensions (external contour 11) with a length or width that is the same as micro-device 90. In some embodiments, frame 10 has a length in the range of 400-500 μm, for example 430-450 μm and a width in the range of 250-350 μm, for example 275-285 μm. Micro-device 90, component 20, and frame 10 can have a thickness no greater than 100 μm, no greater than 50 μm, no greater than 20 μm, no greater than 10 μm, no greater than 5 μm, or no greater than 2 μm, for example in the range of 1-5 μm.

Embodiments of the present disclosure provide micro-devices 90 comprising frames 10 suspending components 20 with cantilever supports 30. Frames 10 have an internal frame contour 13 that is non-rectangular, comprise slits 12, or both. By providing a non-rectangular frame 10, micro-device 90 is more readily micro-transfer printed from a micro-device source wafer 60 to a target substrate 50 since it has a greater area that can be contacted by a stamp post of stamp 40 having a shape similar to a shape of frame 10. Moreover, the non-rectangular shape of frame 10 with slits 12 provides external or exposed corners 18 (e.g., having an angle greater than 180 degrees, for example 270 degrees) that facilitate rapid sacrificial portion 64 etching due to the exposed molecular bonds, shown in FIG. 1B. Rapid sacrificial portion 64 etching reduces undesirable etching of component 20 and frame 10 and increases manufacturing throughput, improving yields and reducing costs.

Component 20 can be any structure useful in combination with frame 10, for example an active or passive device suspended from frame 10, for example over substrate cavity 52. Component 20 can be an electrically responsive device such as a micro-electromechanical device and can comprise piezoelectric material and micro-device electrodes 22. Component 20 can be an acoustic filter or acoustic resonator. Component 20 can comprise piezoelectric material such as KNN, AlN, or PZT or a semiconductor epitaxial layer, dielectrics such as silicon oxides and nitrides, and electrically conductive materials such as metals. Micro-device electrodes 22 can be patterned and disposed on a top and bottom of component 20 or only one side, for example the top side opposite substrate cavity 52.

Component 20 and frame 10 can comprise any one or more of a combination of semiconductor, conductive metals, or dielectric materials, such as inorganic oxides (e.g., silicon oxide), nitrides (e.g., silicon nitride), or organic materials such as photoresists, resins or epoxies. Component 20 and frame 10 can be constructed using photolithographic methods and materials known in the art. Target substrate 50 can be any useful substrate on or in which micro-device 90 can be disposed or formed, for example glass, polymer, semiconductor, or compound semiconductor materials as found in the integrated circuit industry. Component 20 and frame 10 can be coated or encapsulated, for example with an organic (e.g., a resin) or inorganic (e.g., an oxide or nitride) dielectric. Cantilever supports 30 can have a width or length, or both, less than one third of a width or length, or both, respectively, of component 20, for example having a width and length of no more than (e.g., about) 50 by 25 μm. Gaps 16 can have a width from one quarter to four times a width or length of component 20, for example 10-30 μm or 20 μm.

Substrate circuit 88 can be disposed in or on target substrate 50, for example native to and constructed on a semiconductor target substrate 50 or micro-transfer printed to target substrate 50 and can control, respond to, or interact with micro-device 90, for example with component 20. Multiple micro-devices 90 controlled by substrate circuit 88 can be disposed on target substrate 50.

If substrate circuit 88 is native to and formed in or on target substrate 50, compound semiconductor substrate materials are useful because they can provide semiconductor materials useful in high-frequency electronic circuits, for example GaAs, GaN, InP and other III/V or II/VI compound semiconductor materials. If substrate circuit 88 is not native to target substrate 50, substrate circuit 88 can be an integrated circuit formed in a source wafer and disposed on target substrate 50 as a bare die, for example by micro-transfer printing. Substrate circuit 88 integrated circuit can comprise a broken (e.g., fractured) or separated micro-device tether 66 in consequence. Substrate circuit 88 can be an integrated circuit formed using photolithographic methods and materials known in the art.

Substrate electrodes 85 can be, comprise, or electrically connect to an electrical substrate contact pad 84. Micro-device electrodes 22 can electrically connect to substrate electrodes 85 or substrate contact pads 84. Micro-devices 90 can comprise electrically conductive connection posts 24 that extend (e.g., protrude) from a bottom side of frame 10 toward target substrate 50 in electrical contact with substrate electrode 85 or substrate contact pad 84. Connection posts 24 can contact or pierce substrate electrode 85 or substrate contact pad 84 to make an electrical connection and substrate electrode 85 or substrate contact pad 84 can be electrically connected to substrate circuit 88, for example with wires or metal traces, thus connecting any circuit in micro-device 90 or component 20 with substrate circuit 88. Substrate electrodes 85 or substrate contact pads 84 can be metal or other electrical conductors and can be formed using photolithographic materials and methods known in the art.

Connection posts 24 can be pyramidal or have a triangular cross section and have a sharp point. Connection posts 24 can be coated metal over a dielectric structure 28 and can be connected with vias (for example through-silicon or through-dielectric vias) through frame 10 to a substrate circuit 88.

Micro-device 90 can be disposed on target substrate 50 by micro-transfer printing micro-device 90 from a micro-device source wafer 60. In consequence of micro-transfer printing, micro-device 90 can comprise a broken (e.g., fractured) or separated micro-device tether 66.

Reference is made throughout the present description to examples of micro-transfer printing with stamp 40 when describing certain examples of printing micro-devices 90. Similar other embodiments are expressly contemplated where a transfer device that is not a stamp 40 is used to similarly print micro-devices 90. For example, in some embodiments, a transfer device that is a vacuum-based or electrostatic transfer device can be used to print micro-devices 90. A vacuum-based or electrostatic transfer device can comprise a plurality of transfer posts, each transfer post being constructed and arranged to pick up a single micro-device 90 (similarly to stamp posts in stamp 40).

According to some embodiments, micro-transfer printing can include any method of transferring micro-devices 90 from a source wafer (e.g., micro-device source wafer 60) to a destination substrate (e.g., target substrate 50) by contacting micro-devices 90 on micro-device source wafer 60 with a patterned or unpatterned stamp surface of a stamp 40 to remove micro-devices 90 from micro-device source wafer 60, transferring stamp 40 and contacted micro-devices 90 to target substrate 50, and contacting micro-devices 90 to a surface of target substrate 50. Micro-devices 90 can be adhered to stamp 40 or target substrate 50 by, for example, van der Waals forces, electrostatic forces, magnetic forces, chemical forces, adhesives, or any combination of the above. In some embodiments, micro-devices 90 are adhered to stamp 40 with separation-rate-dependent adhesion, for example kinetic control of viscoelastic stamp materials such as can be found in elastomeric transfer devices such as a PDMS stamp 40. Stamps 40 can be patterned or unpatterned and can comprise stamp posts having a stamp post area on distal end 42 of stamp posts. Distal end 42 of the stamp posts can be structured. Stamp posts can have a length, a width, or both a length and a width, similar or substantially equal to a length, a width, or both a length and a width of frame 10. Distal end 42 of stamp posts can have a shape corresponding to frame 10. In some embodiments, distal end 42 of the stamp posts can have a shape similar to frame 10 but without slits 12, as shown in FIG. 11. In some embodiments, stamp posts each have a contact surface of substantially identical area. In exemplary methods, a viscoelastic elastomer (e.g., PDMS) stamp 40 (e.g., comprising a plurality of stamp posts) is constructed and arranged to retrieve and transfer micro-devices 90 from their native micro-device source wafer 60 onto non-native target substrates 50. In some embodiments, stamp 40 mounts onto motion-plus-optics machinery (e.g., an opto-mechatronic motion platform) that can precisely control stamp 40 alignment and kinetics with respect to both micro-device source wafers 60 and target substrates 50. During micro-transfer printing, the motion platform brings stamp 40 into contact with micro-devices 90 on micro-device source wafer 60, with optical alignment performed before contact. Rapid upward movement of the print-head (or, in some embodiments, downward movement of micro-device source wafer 60) breaks (e.g., fractures) or separates micro-device tether(s) 66 forming broken (e.g., fractured) or separated micro-device tethers 66, transferring micro-devices 90 to stamp 40 or stamp posts. The populated stamp 40 then travels to target substrate 50 (or vice versa) and one or more micro-devices 90 are then aligned to substrate cavities 52 in target substrate 50 and printed.

Sacrificial portions 64 are sacrificed, for example by etching sacrificial portions 64 to form a space between etch-stop layer 70 and micro-device source wafer 60, so that micro-devices 90 are suspended over micro-device source wafer 60 and attached to anchors 68 of micro-device source wafer 60 by micro-device tethers 66 that maintain the physical position of micro-devices 90 relative to (e.g., with respect to) micro-device source wafer 60 after sacrificial portions 64 are etched. (Micro-devices 90 are said to comprise at least a portion of a micro-device tether 66, which may be broken or separated as a result of a pick-up portion of a print step.) Stamp 40 is moved into position relative to micro-device source wafer 60, for example by an opto-mechatronic motion platform and micro-devices 90 are picked up from micro-device source wafer 60 by adhering micro-devices 90 to stamp 40, for example by pressing stamp 40 against frames 10 on micro-device source wafer 60 with the motion platform and adhering micro-devices 90 to distal ends 42 of the stamp posts, for example with van der Waals or electrostatic forces.

A micro-device source wafer 60 can be any source wafer or substrate with transfer printable micro-devices 90 that can be transferred with a transfer device (e.g., a stamp 40). For example, a micro-device source wafer 60 can be or comprise a semiconductor (e.g., silicon) in a crystalline or non-crystalline form, a compound semiconductor (e.g., comprising GaN or GaAs), a glass, a polymer, a sapphire, or a quartz wafer. Sacrificial portions 64 can be formed of a patterned oxide (e.g., silicon dioxide) or nitride (e.g., silicon nitride) layer or can be an anisotropically etchable portion of sacrificial layer 62 of micro-device source wafer 60. Typically, micro-device source wafers 60 are smaller than target substrates 50.

Micro-devices 90 can be unpackaged dice (each an unpackaged die) transferred directly from native micro-device source wafers 60 on or in which micro-devices 90 are constructed to target substrate 50.

Anchors 68 and micro-device tethers 66 can each be or can comprise portions of micro-device source wafer 60 that are not sacrificial portions 64 and can include layers formed on micro-device source wafers 60 or micro-devices 90, for example dielectric or metal layers and for example layers formed as a part of photolithographic processes used to construct micro-devices 90.

Target substrate 50 can be any destination substrate or target substrate to which micro-devices 90 are transferred (e.g., micro-transfer printed), for example flat-panel display substrates, printed circuit boards, or similar substrates can be used in various embodiments. Target substrates 50 can be, for example substrates comprising one or more of glass, polymer, quartz, ceramics, metal, and sapphire. Target substrates 50 can be semiconductor substrates (for example silicon) or compound semiconductor substrates.

In some embodiments, a layer of adhesive 86, such as a layer of resin, polymer, or epoxy adheres micro-devices 90 onto target substrate 50 and can be disposed, for example by coating or lamination. In some embodiments, a layer of adhesive 86 is disposed in a pattern. A layer of adhesive 86 can be disposed using inkjet, screening, or photolithographic techniques, for example. In some embodiments, a layer of adhesive 86 is coated, for example with a spin, spray, or slot coater, and then patterned, for example using photolithographic techniques.

Patterned electrical conductors (e.g., wires, traces, or electrodes (e.g., electrical contact pads 84) such as those found on printed circuit boards, flat-panel display substrates, and in thin-film circuits) can be formed on any combination of micro-devices 90 and target substrate 50, and any one can comprise substrate electrodes 85 (e.g., contact pads 84) that electrically connect to micro-devices 90. Such patterned electrical conductors and electrodes (e.g., contact pads 84) can comprise, for example, metal, transparent conductive oxides, or cured conductive inks and can be constructed using photolithographic methods and materials, for example metals such as aluminum, gold, or silver deposited by evaporation and patterned using pattern-wise exposed, cured, and etched photoresists, or constructed using imprinting methods and materials or inkjet printers and materials, for example comprising cured conductive inks deposited on a surface or provided in micro-channels in or on target substrate 50 or micro-devices 90, or both.

Adhesive 86 can be a curable or cured adhesive 86. Adhesive 86 can be an uncured adhesive 86 that is subsequently cured. Uncured adhesive 86 can be an uncured adhesive 86 that is deposited on a surface of target substrate 50 as a liquid, for example by laminating, coating, or spraying adhesive 86 onto substrate surface of target substrate 50. Adhesive 86 can be a soft-cured adhesive 86, for example an adhesive 86 from which at least some, a majority, or a substantial majority of solvents or other volatile materials are evaporated or otherwise removed or driven out from uncured adhesive 86 that is still relatively malleable, compliant, or conformable compared to a hard-cured adhesive 86 and can be shaped or otherwise deformed by pressing against the soft-cured adhesive 86, for example with a component 20. An uncured or soft-cured adhesive 86 can be hard cured by, for example, by heating or exposure to electromagnetic radiation 28 that renders adhesive 86 a cured, relatively rigid, non-compliant, non-conformable, and solid adhesive 86 with substantially reduced stickiness or adhesion compared to uncured or soft-cured adhesive 86. Thus, in some embodiments, adhesive 86 can be completely uncured, soft-cured, or hard-cured at various stages of constructing printed structures 99 of the present disclosure. A layer of soft-cured (e.g., partially cured) adhesive 86 can be patterned, for example by photolithographic processing using masks to expose the layer of uncured adhesive 86 and removing either the exposed or unexposed adhesive 86 to form a patterned layer of soft-cured adhesive 86 on target substrate 50. According to embodiments of the present disclosure, adhesive 86 can comprise an organic material, a polymer, a resin, or an epoxy. According to some embodiments, adhesive 86 is a photoresist. Adhesive 86 can be a positive photoresist, for example AZ1505 or AZ10XT from Microchemicals GmbH. Target substrate 50 can be provided in step 120 using photolithographic materials and methods known in the art.

Examples of micro-transfer printing processes suitable for disposing components 20 onto target substrates 50 are described in Inorganic light-emitting diode displays using micro-transfer printing (Journal of the Society for Information Display, 2017, DOI #10.1002/jsid.610, 1071-0922/17/2510-0610, pages 589-609), U.S. Pat. No. 8,722,458 entitled Optical Systems Fabricated by Printing-Based Assembly, U.S. patent application Ser. No. 15/461,703 entitled Pressure-Activated Electrical Interconnection by Micro-Transfer Printing, U.S. Pat. No. 8,889,485 entitled Methods for Surface Attachment of Flipped Active Components, U.S. patent application Ser. No. 14/822,864 entitled Chiplets with Connection Posts, U.S. patent application Ser. No. 14/743,788 entitled Micro-Assembled LED Displays and Lighting Elements, and U.S. patent application Ser. No. 15/373,865, entitled Micro-Transfer Printable LED Component, the disclosure of each of which is incorporated herein by reference in its entirety. Examples of micro-transfer printed acoustic wave filter devices are described in U.S. patent application Ser. No. 15/047,250, entitled Micro-Transfer Printed Acoustic Wave Filter Device, the disclosure of which is incorporated herein by reference in its entirety.

For a discussion of various micro-transfer printing techniques, see also U.S. Pat. Nos. 7,622,367 and 8,506,867, each of which is hereby incorporated by reference in its entirety. Micro-transfer printing using compound micro-assembly structures and methods can also be used in certain embodiments, for example, as described in U.S. patent application Ser. No. 14/822,868, filed Aug. 10, 2015, entitled Compound Micro-Assembly Strategies and Devices, which is hereby also incorporated by reference in its entirety. In some embodiments, any one or more of micro-devices 90 is a compound micro-assembled structure (e.g., a compound micro-assembled macro-system).

According to various embodiments, micro-device source wafer 60 can be provided with micro-devices 90, patterned sacrificial portions 64, micro-device tethers 66, and anchors 68 already formed, or they can be constructed as part of a method in accordance with certain embodiments. Micro-device source wafer 60 and micro-devices 90, micro-transfer printing device (e.g., a stamp 40), and target substrate 50 can be made separately and at different times or in different temporal orders or locations and provided in various process states.

In certain embodiments, target substrate 50 is or comprises a member selected from the group consisting of polymer (e.g., plastic, polyimide, PEN, or PET), resin, metal (e.g., metal foil) glass, ceramic, a semiconductor, and sapphire. In certain embodiments, target substrate 50 has a thickness from 5 μm to 20 mm (e.g., 5 to 10 μm, 10 to 50 μm, 50 to 100 μm, 100 to 200 μm, 200 to 500 μm, 500 μm to 0.5 mm, 0.5 to 1 mm, 1 mm to 5 mm, 5 mm to 10 mm, or 10 mm to 20 mm).

Micro-devices 90, frames 10, or components 20, in certain embodiments, can be constructed using foundry fabrication processes used in the art. Layers of materials can be used, including materials such as metals, oxides, nitrides and other materials used in the integrated-circuit art. Micro-devices 90 or components 20 can have different sizes, for example, at least 100 square μm, at least 1,000 square μm, at least 10,000 square μm, at least 100,000 square μm, or at least 1 square mm. Alternatively or additionally, micro-devices 90 can be no more than 100 square μm, no more than 1,000 square μm, no more than 10,000 square μm, no more than 100,000 square μm, or no more than 1 square mm, for example. Micro-devices 90, frames 10, or components 20 can have variable aspect ratios, for example between 1:1 and 10:1 (e.g., 1:1, 2:1, 5:1, or 10:1). Micro-devices 90 or components 20 can be rectangular or can have other shapes, such as polygonal or circular shapes for example.

Various embodiments of structures and methods were described herein. Structures and methods were variously described as transferring micro-devices 90, printing micro-devices 90, or micro-transferring micro-devices 90. Micro-transfer-printing involves using a transfer device (e.g., an elastomeric stamp 40, such as a PDMS stamp 40) to transfer a micro-device 90 using controlled adhesion. For example, an exemplary transfer device can use kinetic or shear-assisted control of adhesion between a transfer device and a micro-device 90. It is contemplated that, in certain embodiments, where a method is described as including micro-transfer-printing a micro-devices 90, other analogous embodiments exist using a different transfer method. As used herein, transferring a micro-device 90 (e.g., from a micro-device source wafer 60 to a target substrate 50) can be accomplished using any one or more of a variety of known techniques. For example, in certain embodiments, a pick-and-place method can be used. As another example, in certain embodiments, a flip-chip method can be used (e.g., involving an intermediate, handle or carrier substrate). In methods according to certain embodiments, a vacuum tool or other transfer device is used to transfer a micro-devices 90.

As is understood by those skilled in the art, the terms “over” and “under” and “top” and “bottom” are relative terms and can be interchanged in reference to different orientations of the layers, elements, and substrates included in various embodiments of the present disclosure. Furthermore, a first layer or first element “on” a second layer or second element, respectively, is a relative orientation of the first layer or first element to the second layer or second element, respectively, that does not preclude additional layers being disposed therebetween. For example, a first layer on a second layer, in some implementations, means a first layer directly on and in contact with a second layer. In other implementations, a first layer on a second layer includes a first layer and a second layer with another layer therebetween (e.g., and in mutual contact). In some embodiments, a micro-device 90 has connection posts 24 extending therefrom and is disposed “on” a target substrate 50 with connection posts 24 disposed between target substrate 50 and micro-device 90.

Throughout the description, where apparatus and systems are described as having, including, or comprising specific elements, or where processes and methods are described as having, including, or comprising specific steps, it is contemplated that, additionally, there are apparatus and systems of the disclosed technology that consist essentially of, or consist of, the recited elements, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously.

Having described certain implementations of embodiments, it will now become apparent to one of skill in the art that other implementations incorporating the concepts of the disclosure may be used. The disclosure has been described in detail with particular reference to certain embodiments thereof, but it will be understood that variations and modifications can be effected within the spirit and scope of the following claims.

### PARTS LIST

A cross section line
B cross section line
10 frame
11 external frame contour
12 slit
13 internal frame contour
16 gap
18 exposed corner
20 component
22 micro-device electrode
22B bottom electrode
22T top electrode
24 connection post
26 component material
28 dielectric structure
30 cantilever support
40 stamp
42 distal end
44 stamp opening/stamp cavity
50 target substrate
52 substrate cavity
54 cap
60 micro-device source wafer
62 sacrificial layer
64 sacrificial portion
66 tether
68 anchor
70 etch-stop layer
84 contact pad
85 substrate electrode
86 adhesive
88 substrate circuit
90 micro-device
5 provide source wafer step
110 form device step
120 optional dispose cap step
130 release structure from source wafer step
140 print structure to target substrate step
150 optional dispose cap step
160 provide target substrate step
170 form cavity step

What is claimed:

1. A micro-device, comprising:
a frame; and
a component separated from the frame by a gap except where the component is connected to the frame with one or more cantilever supports extending from the component to the frame,
wherein an internal contour of the frame is non-rectangular.

2. The micro-device of claim 1, wherein the internal contour of the frame follows an external contour of the component and the one or more cantilever supports except where the one or more cantilever supports are connected to the frame.

3. The micro-device of claim 1, wherein the internal contour of the frame comprises one or more slits extending from the gap into the frame.

4. The micro-device of claim 1, wherein an external contour of the frame is rectangular.

5. The micro-device of claim 1, wherein an external contour of the frame comprises one or more slits extending into the frame.

6. The micro-device of claim 1, wherein the gap separating the frame from the component has a uniform width except where the one or more cantilever supports are connected to the frame.

7. The micro-device of claim 1, wherein the component is substantially rectangular.

8. The micro-device of claim 1, wherein the component comprises a piezoelectric material, the micro-device comprises electrodes, and the electrodes extend over the one or more cantilever supports to the frame.

9. The micro-device of claim 1, comprising at least a portion of a tether (e.g., extending from the frame).

10. The micro-device of claim 1, wherein the frame and the component each comprise one or more same materials.

11. The micro-device of claim 1, comprising a cap disposed over the frame and component and adhered to the frame.

12. The micro-device of claim 1, wherein the one or more cantilever supports is a plurality of cantilever supports.

13. The micro-device of claim 12, wherein the plurality of cantilever supports comprises cantilever supports that connect to the component at different sides of the component.

14. A micro-device structure, comprising a target substrate and one or more micro-devices according to claim 1 disposed on the target substrate.

15. The micro-device structure of claim 14, comprising a cavity in the target substrate, wherein the component is disposed on the target substrate over the cavity.

16. The micro-device structure of claim 14, comprising a cap disposed over the micro-device and adhered to the target substrate.

17. A micro-device wafer, comprising:
a source wafer comprising a sacrificial layer, wherein the sacrificial layer comprises a sacrificial portion adjacent to an anchor; and
a micro-device according to claim 1 disposed entirely over the sacrificial portion.

18. A micro-device wafer, comprising:
a source wafer; and
a micro-device according to claim 1 suspended over the source wafer by at least one tether, wherein the at least one tether is connected to the source wafer and the micro-device is suspended such that a space is defined between the source wafer and the micro-device.

19. A method of making a micro-device structure, comprising:
providing a source wafer comprising a sacrificial layer comprising sacrificial portions separated by anchor portions;
forming a plurality of micro-devices each comprising a frame and a component separated from the frame by a gap except where the component is connected to the frame with one or more cantilever supports extending from the component to the frame, each of the micro-devices disposed entirely directly over one of the sacrificial portions.

20. The method of claim 19, comprising, for each of the micro-devices, disposing a cap over the micro-device and adhering the cap to the frame of the micro-device.

21. The method of claim 19, comprising:
releasing the micro-devices by etching the sacrificial portions; and
printing the micro-devices from the source wafer to a target substrate; and
optionally disposing a cap over the micro-device and adhering the cap to the target substrate.

22. The method of claim 21, wherein printing the micro-devices comprises micro-transfer printing the micro-devices with a stamp, wherein the stamp comprises posts and each of the posts has a distal end having a shape corresponding to the frame of one of the micro-devices such that the post contacts the frame and not the component of the one of the micro-devices during micro-transfer printing.

23. A micro-device, comprising:
a frame; and
a component separated from the frame by a gap and connected to the frame only with one or more cantilever supports extending from the component to the frame,
wherein the frame comprises one or more slits extending into the frame.

24. The micro-device of claim 23, wherein at least one of the one or more slits extends from the gap into the frame.

25. The micro-device of claim 23, wherein an external contour of the frame comprises at least one of the one or more slits.

26. A micro-device structure, comprising:
a target substrate comprising a cavity; and
a micro-device according to claim 23 disposed on or over the target substrate such that the component is disposed over the cavity.
